(19) United States
(12) Patent Application Publication
(10) Pub. No.: US 2024/0396303 A1
(43) Pub. Date: Nov. 28, 2024

(54) VERTICAL CAVITY SURFACE EMITTING LASER ELEMENT

(71) Applicant: NICHIA CORPORATION, Anan-shi (JP)

(72) Inventors: Kenichi TERAO, Tokushima-shi (JP); Yoshihiro HARA, Anan-shi (JP)

(21) Appl. No.: 18/673,082

(22) Filed: May 23, 2024

(30) Foreign Application Priority Data
May 26, 2023 (JP) 2023-087255
Nov. 30, 2023 (JP) 2023-202604

(51) Int. Cl. H01S 5/183

(52) U.S. Cl. CPC H01S 5/18361

(57) ABSTRACT

A vertical cavity surface emitting laser element includes a substrate, an AlGaN foundation layer, a multilayer reflective film, and an n-side semiconductor layer, an active layer, and a p-side semiconductor layer. The substrate contains GaN. The AlGaN foundation layer is arranged on an upper surface of the substrate. The multilayer reflective film is arranged on an upper surface of the foundation layer and including an AlInN layer. The n-side semiconductor layer, the active layer, and the p-side semiconductor layer are arranged above the multilayer reflective film.

### CROSS REFERENCE TO RELATED APPLICATIONS

This application claims priority to Japanese Patent Application No. 2023-87255, filed on May 26, 2023, and Japanese Patent Application No. 2023-202604, filed on Nov. 30, 2023. The entire disclosures of Japanese Patent Application Nos. 2023-87255 and 2023-202604 are hereby incorporated herein by reference.

### BACKGROUND

### Technical Field

The present disclosure relates to a vertical cavity surface emitting laser element.

### Background Art

As an example of a semiconductor element, a vertical cavity surface emitting laser element including a GaN-based semiconductor layer and a multilayer reflective film has been proposed (e.g., JP 2003-101141 A).

### SUMMARY

Providing a GaN layer between a substrate and a multilayer reflective film results in rough surface morphology in some cases. This may lead to reduction in flatness of the multilayer reflective film.

According to one aspect of the present disclosure, a vertical cavity surface emitting laser element includes a substrate, an AlGaN foundation layer, a multilayer reflective film, and an n-side semiconductor layer, an active layer, and a p-side semiconductor layer. The substrate contains GaN. The AlGaN foundation layer is arranged on an upper surface of the substrate. The multilayer reflective film is arranged on an upper surface of the foundation layer and including an AlInN layer. The n-side semiconductor layer, the active layer, and the p-side semiconductor layer are arranged above the multilayer reflective film.

According to certain embodiments of the present disclosure, a vertical cavity surface emitting laser element that can reduce variation in a threshold current can be provided.

### BRIEF DESCRIPTION OF DRAWINGS

FIG. 1 is a schematic cross-sectional view illustrating a vertical cavity surface emitting laser element according to one embodiment.

FIG. 2 is a schematic cross-sectional view illustrating a structure of a vertical cavity surface emitting laser element of an example.

FIG. 3 is a schematic cross-sectional view illustrating a structure of a vertical cavity surface emitting laser element of a comparative example.

FIG. 4 is a diagram showing cumulative distributions of threshold currents in a plurality of vertical cavity surface emitting laser elements in the example and the comparative example.

### DETAILED DESCRIPTION

The embodiments described below are merely intended to give a concrete form to the technical idea of the present disclosure, and the present disclosure is not limited to the following description unless specifically stated otherwise. The contents described in one embodiment or example can be applied to another embodiment or example. The size, thickness, positional relationship, or the like of members illustrated in the drawings may be exaggerated for clarity of description. The same names and reference signs denote members that are the same as or of the same material in principle, and repeated description thereof is omitted as appropriate. For each member of the surface emitting laser element, a light extraction surface side of the surface emitting laser element is sometimes referred to as a first surface or a lower surface, and a side opposite to the light extraction surface is sometimes referred to as a second surface or an upper surface.

### First Embodiment: Vertical Cavity Surface Emitting Laser Element

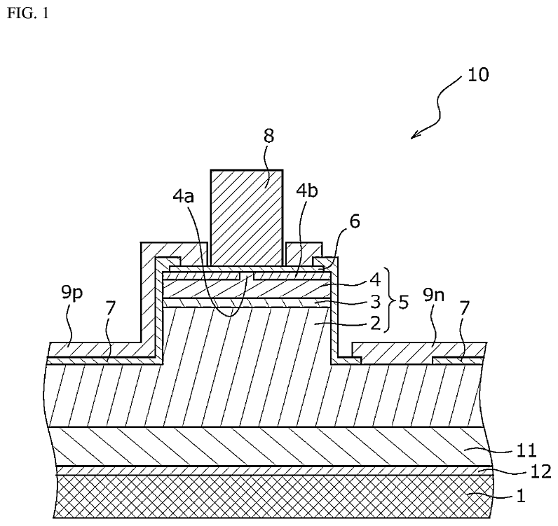

As illustrated in FIG. 1, a vertical cavity surface emitting laser element 10 according to a first embodiment of the present disclosure includes a substrate 1 containing GaN, an AlGaN foundation layer 12 (hereinafter, referred to as a foundation layer 12) arranged on an upper surface of the substrate 1, a multilayer reflective film 11 arranged on an upper surface of the foundation layer 12 and including an AlInN layer, and a semiconductor layered body 5 arranged above the multilayer reflective film 11 and including an n-side semiconductor layer 2, an active layer 3, and a p-side semiconductor layer 4. The foundation layer 12 functions as a first layer during crystal growth on the substrate 1. In contrast to the first embodiment of the present disclosure, when a foundation layer of a GaN layer is formed on the substrate 1, reflectance is not sufficient in some cases. Assuming that this is caused by an insufficient flatness of the surface morphology of the foundation layer, the foundation layer 12 of an AlGaN layer has been formed as in the first embodiment of the present disclosure, resulting in improvement of the surface morphology of the foundation layer 12. This improvement is thought to be due to that the diffusion length of Al adatoms during crystal growth is longer than the diffusion length of Ga. The term “adatom” as used herein refers to an atom lying on a surface of a layer. Improving the surface morphology of the foundation layer 12 allows for improving the flatness of the multilayer reflective film 11 provided on the foundation layer 12, which can improve substantial reflectance of the multilayer reflective film 11. Thus, variation in a threshold current in the vertical cavity surface emitting laser element 10 can be reduced. In addition, an average value of threshold currents across a plurality of the vertical cavity surface emitting laser elements 10 can be reduced. The threshold current means a minimum current required for laser oscillation of the vertical cavity surface emitting laser element 10. The vertical cavity surface emitting laser element 10 preferably includes an electrode layer 6 on the p-side semiconductor layer 4, and a reflective layer 8 on the electrode layer 6. With such a configuration, light reflection characteristics of the reflective layer 8 can be improved. Also, the vertical cavity surface emitting laser element 10 preferably includes an electrode layer 9n on the n-side semiconductor layer 2. With such a configuration, the current does not need to pass through the multilayer reflective film 11, and thus it is not necessary to dope the multilayer reflective film 11 with an n-type impurity.

Therefore, the reflectance of the multilayer reflective film 11 can be further improved. The vertical cavity surface emitting laser element 10 according to the first embodiment of the present disclosure emits laser light from the substrate 1 side.

### Substrate 1

The substrate 1 functions as a foundation for growing the semiconductor layered body 5 including the n-side semiconductor layer 2, the active layer 3, and the p-side semiconductor layer 4. The substrate 1 can be appropriately selected according to the material of the semiconductor layered body 5, and preferably contains GaN. In particular, a substrate made of a single layer of GaN is preferably used as the substrate 1. Using a substrate made of a single layer of GaN as the substrate 1 allows for improving crystallinity of the foundation layer 12 provided on the upper surface of the substrate 1. The substrate 1 may have an off-angle with respect to a main surface of the substrate 1. When a substrate having a predetermined off-angle and an appropriate atomic step interval is used as the substrate 1, the foundation layer 12 can be grown with good crystallinity. A direction perpendicular to the main surface of the substrate 1 is, for example, a <0001> direction. The direction perpendicular to the main surface of the substrate 1 may be parallel to the <0001> direction, or may be inclined at a predetermined off-angle with respect to the <0001> direction. In addition, a direction component along a <11-20> axis of the off-angle is in a range of, for example, 0.4° to 10°. A direction component along a <1-100> axis of the off-angle is in a range of, for example, 0° to 0.4°. A combined off-angle obtained by combining the direction component along the <11-20> axis and the direction component along the <1-100> axis of the off-angle is in a range of, for example, 0.4° to 10°, and preferably in a range of 0.4° to 0.6°. Setting the combined off-angle to 0.6° or less can help prevent step bunching and can help prevent deterioration of the surface morphology of the foundation layer 12. In addition, setting the combined off-angle to 0.4° or more can help prevent the occurrence of hillocks around screw dislocations and can help prevent deterioration of the surface morphology. The upper and lower surfaces of the substrate 1 are preferably parallel to each other, and the upper and lower surfaces are preferably flat. With such a configuration, the quality of laser light emitted from the vertical cavity surface emitting laser element 10 can be improved. The surface of the substrate 1 may have slight unevenness, and the unevenness may have a surface roughness Ra in a range of, for example, 0 nm to 1 nm. Alternatively, the unevenness may have an arithmetic average roughness Sa in a range of, for example, 0 nm to 1 nm. The substrate 1 having a thickness in a range of, for example, 100 m to 1000 m can be used.

### Foundation Layer 12

The foundation layer 12 is arranged on the upper surface of the substrate 1. That is, the foundation layer 12 is disposed in contact with the upper surface of the substrate 1. The foundation layer 12 is a layer formed as a first layer when crystal growth is performed on the upper surface of the substrate 1, and is a layer that allows a layer formed on the foundation layer 12 to have good crystallinity. For example, if the substrate 1 is scratched and the foundation layer 12 is not provided, a layer formed on the substrate 1 reflects the scratch of the substrate 1, deteriorating the surface morphology. Even when the surface of the substrate 1 is rough, the influence of the roughness can be reduced by the foundation layer 12, and thus the layer formed on the foundation layer 12 can be in a good state. The foundation layer 12 is preferably a single layer of an AlGaN layer. Specifically, the foundation layer 12 is AlₓGa₁₋ₓN, in which x is 0.004 or greater and less than 0.08, preferably 0.01 or greater and less than 0.08, and more preferably in a range of 0.01 to 0.05. This allows for improving the surface morphology of the foundation layer 12. As an example, x is in a range of 0.015 to 0.035. This allows for obtaining the effect of improving the surface morphology while reducing the likelihood of cracks in the foundation layer 12. When a GaN layer not containing Al is provided as the foundation layer, irregularity is likely to occur on the surface due to the diffusion length of Ga adatoms being small during crystal growth, and accordingly the flatness of the surface morphology is likely to decrease. When the flatness of the surface morphology is insufficient, parallelism of the pair of mirrors constituting the vertical cavity surface emitting laser element 10 decreases, so that the feedback ratio of light reciprocating in the resonator decreases. This may lead to reduction in the substantial reflectance of the multilayer reflective film 11 provided on the upper surface of the foundation layer, and thus, to deterioration of the threshold current. Therefore, by improving the surface morphology of the foundation layer 12, the reflectance of the multilayer reflective film 11 can be improved. As a result, the deterioration of the threshold current of the vertical cavity surface emitting laser element 10 can be inhibited and the variation in the threshold current can be reduced. While it is thought that the effect of improving the surface morphology can be enhanced by increasing the Al composition ratio in the foundation layer 12, the likelihood of cracks in the foundation layer 12 can be reduced by reducing the Al composition ratio. Therefore, by setting the Al composition ratio in the above-described range, it is possible to achieve a balance between improvement in the surface morphology and reduction of cracks, so that it is possible to improve the surface morphology and reduce cracks. The foundation layer 12 may be an amorphous layer, may be a single crystal layer, or may be a layer in which configurations of these layers are mixed. Of these, a layer that is not an amorphous layer is preferable, a single crystal layer is more preferable, and a single layer of a single crystal AlGaN layer is still more preferable. With the foundation layer 12 of a single-crystal layer, it is possible to reduce the possibility of dislocation in a layer formed on the foundation layer 12. The foundation layer 12 has a thickness of, for example, 3.5 μm or less, preferably 3.0 μm or less, more preferably 2.5 μm or less, and still more preferably 1.5 μm or less. With this thickness, it is possible to reduce the likelihood of cracks in the foundation layer 12. Further, the foundation layer 12 has a thickness of, for example, 0.1 μm or more, preferably 0.2 μm or more. With this thickness, when the surface morphology of the substrate 1 is rough, an influence thereof can be more effectively reduced. The upper and lower surfaces of the foundation layer 12 may be flat or may have slight unevenness. The upper surface of the foundation layer 12 may have an arithmetic average height Sa of, for example, 3.0 nm or less. Alternatively, the surface roughness Ra is, for example, 3.0 nm or less. The foundation layer 12 can be formed by epitaxial growth employing a method known in the art, for example, a metal organic chemical vapor deposition method (MOCVD).

### Multilayer Reflective Film 11

The multilayer reflective film 11 is disposed on the upper surface of the foundation layer 12. To obtain a desired reflectance, the material, film thickness, number of layers, and the like constituting each layer in the multilayer reflective film 11 can be selected as appropriate. Specifically, examples of the material constituting each layer include AlN, InN, GaN, AlGaN, InGaN, and AlInGaN. In addition, examples of a combination of these materials include AlInN/GaN, AlInN/AlGaN, and AlInN/AlN. In particular, the multilayer reflective film 11 preferably includes an AlInN layer, and more preferably uses a combination of an AlInN layer and a GaN layer as materials. The AlInN layer preferably has an In composition ratio in a range of 1% to 30%. Within this range, a lattice constant of the AlInN layer and a lattice constant of the GaN layer can be close to each other, and the likelihood of warping or cracking of a wafer during growth of the multilayer reflective film 11 can be reduced. For example, in the multilayer reflective film 11, the thickness of each layer constituting the multilayer reflective film 11 can be λ/(4n) (in which λ is an oscillation wavelength of a laser, and n is a refractive index of the medium constituting each layer), and can be set as appropriate based on the oscillation wavelength λ and the refractive index n of the material being used. Specifically, the thickness of each layer is preferably an odd number of times of λ/(4n). For example, when the multilayer reflective film 11 is constituted of AlInN/GaN in a light-emitting element having an oscillation wavelength λ of 450 nm, the thickness of each layer is in a range of, for example, 40 nm to 70 nm. The number of layers in the multilayer reflective film 11 can be set as appropriate according to a characteristic to be obtained. The number of layers in the multilayer reflective film 11 is 2 layers or more and can be in a range of, for example, 5 layers to 100 layers. The entire thickness of the multilayer reflective film 11 is in a range of, for example, 0.05 μm to 10 μm, preferably in a range of 0.1 μm to 10 μm, more preferably in a range of 0.1 μm to 8 μm, and still more preferably in a range of 0.1 μm to 7 μm. Within this range, it is possible to increase the optical output while improving the reflectance of the multilayer reflective film 11. The size and shape of the multilayer reflective film 11 in a top view can be designed as appropriate as long as the multilayer reflective film 11 covers a resonance region. The multilayer reflective film 11 can be formed on the upper surface of the foundation layer 12 by epitaxial growth using a method known in the art, such as MOCVD.

### Semiconductor Layered Body 5

The semiconductor layered body 5 is arranged above the multilayer reflective film 11. That is, the semiconductor layered body 5 may be formed in contact with a surface of the multilayer reflective film 11, or may be formed on the multilayer reflective film 11 via a semiconductor layer, such as an intermediate layer or a buffer layer. In particular, the semiconductor layered body 5 is preferably formed in contact with the surface of the multilayer reflective film 11. The semiconductor layered body 5 preferably includes the n-side semiconductor layer 2, the active layer 3, and the p-side semiconductor layer 4 arranged in this order. The n-side semiconductor layer 2 may include a layer not containing an n-type impurity as long as another of the layers constituting the n-side semiconductor layer 2 contains an n-type impurity, and the p-side semiconductor layer 4 may include a layer not containing a p-type impurity as long as another of the layers constituting the p-side semiconductor layer 4 contains a p-type impurity. An example of the semiconductor layered body 5 is a III-V compound semiconductor. For example, a nitride-based semiconductor material, such as In_{X}Al_{Y}Ga_{1-X-Y}N (0≤X, 0≤Y, X+Y≤1), and InN, AlN, GaN, InGaN, AlGaN, InGaAlN, and the like can be used. Each of these layers can have any appropriate film thickness and layer structure that are known in this field. Specifically, for example, the n-side semiconductor layer 2 made of an In_{X}Al_{Y}Ga_{1-X-Y}N compound semiconductor, the active layer 3 made of an In_{X}Al_{Y}Ga_{1-X-Y}N compound semiconductor, and the p-side semiconductor layer 4 made of an In_{X}Al_{Y}Ga_{1-X-Y}N compound semiconductor may be layered in this order. The n-side semiconductor layer 2 is a single layer or multiple layers, and includes one or more semiconductor layers each doped with an n-type impurity, such as Si or Ge. The active layer 3 has a multiple quantum well structure or a single quantum well structure. The active layer 3 has, for example, a layered structure in which a quantum well layer made of InGaN and a barrier layer made of GaN are alternately layered. The number of layers can be set as appropriate according to a desired characteristic. As the barrier layer, in addition to GaN, InGaN or the like having an In composition lower than the In composition of InGaN of the quantum well layer can be used. The p-side semiconductor layer 4 is a single layer or multiple layers, and can include a p-side cladding layer and a p-side contact layer disposed on the p-side cladding layer. The p-side contact layer is a layer doped with a p-type impurity, for example, Mg. The p-side cladding layer can be a layer in which the p-type impurity is doped or undoped at a concentration lower than that in the p-side contact layer. In this case, the p-side contact layer is the uppermost layer of the p-side semiconductor layer 4. The p-side contact layer is, for example, a GaN layer containing a p-type impurity. A thickness of each of the n-side semiconductor layer 2, the active layer 3, and the p-side semiconductor layer 4 can be set as appropriate. The total film thickness from an upper surface of the multilayer reflective film 11 described below to a lower surface of the reflective layer 8 described below is an integer multiple of λ/(2n_{eq}) (n_{eq} is an equivalent refractive index of a waveguide) and is set to generate a standing wave between the upper surface and the lower surface. Preferably, an antinode portion of the standing wave is arranged in the active layer 3, and a node portion of the standing wave is arranged in a light-transmissive electrode layer 6 described below. Such setting can reduce a threshold current. The shape and size of the semiconductor layered body 5 can be set as appropriate in accordance with the size or the like of a surface emitting element to be obtained. Examples of the shape include polygonal shapes, such as a circle, an ellipse, a square, a rectangle, and a hexagon, in a top view, and examples of the size include a quadrangle with one side in a range of 0.1 mm×0.1 mm to 1.0 mm×1.0 mm, and a circle, a hexagon, or the like with one side or diameter in a range of 0.1 mm to 1 mm. The semiconductor layered body 5 can be formed, for example, on the multilayer reflective film 11 arranged on the upper surface of the foundation layer 12 by epitaxial growth using a method known in the art, such as MOCVD.

As illustrated in FIG. 1, when the semiconductor layered body 5 includes a protruded portion including a resonance region, the semiconductor layered body 5 can have a structure in which, in a region around the protruded portion, the p-side semiconductor layer 4, the active layer 3, and a portion of the n-side semiconductor layer 2 has been removed in a thickness direction and the n-side semiconductor layer 2 is partially exposed. Thus, the electrode layer 6 on the p side and the electrode layer 9n on the n side that are configured to supply a current to the vertical cavity surface emitting laser element 10 can be disposed on the same surface side of the semiconductor layered body 5. After the semiconductor layered body 5 is formed, the protruded portion can be formed by using a known method, such as photolithography or etching. Accordingly, a part of the n-side semiconductor layer 2 is exposed around the protruded portion. A lateral surface of the protruded portion, that is, exposed surfaces in the thickness direction of the n-side semiconductor layer 2, the active layer 3, and the p-side semiconductor layer 4 may be perpendicular or inclined with respect to a surface of the p-side semiconductor layer 4 on a side opposite to the active layer 3. A surface (upper surface) of the p-side semiconductor layer 4 may be a flat surface, or may include protrusions and recesses. When the upper surface of the p-side semiconductor layer 4 is a flat surface, the electrode layer 6 formed on the p-side semiconductor layer 4 can have flat surfaces, thus allowing current concentration caused by bending of the electrode layer 6 or the like to be avoided. The term “flat” used here refers to, for example, a maximum height roughness Rz of the surface of the p-side semiconductor layer 4 being in a range of 0.1 nm to 2 nm. With such a flat surface, the reflective layer 8 described below can be formed flat. The protruded portion is preferably located at a position that allows uniform light emission in a plane of the surface-emitting element. The protruded portion can be set as appropriate according to the planar shape of the semiconductor layered body 5, and can be disposed at any appropriate position in the semiconductor layered body 5 in a top view. Examples thereof include the protruded portion being disposed on an inner side of the semiconductor layered body 5, that is, at a position in which the entire periphery of the protruded portion is surrounded by the n-side semiconductor layer 2.

On the surface of the p-side semiconductor layer 4, a current constriction region 4b preferably surrounds a current injection region 4a to achieve effective resonance. In this case, the shape, thickness, and the like of the current injection region 4a and the current constriction region 4b can be set as appropriate according to the characteristics of the vertical cavity surface emitting laser element 10 to be obtained.

### Electrode Layer 6

The electrode layer 6 is preferably disposed on the p-side semiconductor layer 4. The electrode layer 6 can be formed of a light-transmissive material having a transmittance of 80% or more, preferably 99% or more, with respect to a peak wavelength of laser light oscillated by the vertical cavity surface emitting laser element 10. Examples of the light-transmissive material include a transparent conductive material that has, as a base material, an oxide such as indium-tin oxide (ITO) or indium-zinc oxide (IZO). The thickness of the electrode layer 6 is in a range of, for example, 5 nm to 100 nm. More preferably, the thickness of the electrode layer 6 is in a range of 20 nm to 30 nm. By setting the thickness of the electrode layer 6 within this range, it is possible to reduce absorption of light by the electrode layer 6 and reduce the threshold current. The electrode layer 6 can be formed after exposing the n-side semiconductor layer 2 described below.

### Reflective Layer 8

The reflective layer 8 is preferably disposed as a second reflective layer on a surface of the p-side semiconductor layer 4 including the electrode layer 6. The reflective layer 8 may be disposed, for example, only on the electrode layer 6, or may be disposed extending over a region above the electrode layer 6 and a region above a portion of a surface of the p-side semiconductor layer 4 on which the electrode layer 6 is not provided. When the reflective layer 8 is formed only on the electrode layer 6, the reflective layer 8 can be formed to have flatter surface. With this configuration, the shape of oscillating laser light can be easily controlled. The reflective layer 8 is formed, on a surface of the electrode layer 6, extending over a region directly above the current injection region 4a and a region above the current constriction region 4b around the current injection region 4a. With this configuration, alignment of patterns at the time of forming the reflective layer 8 can be facilitated, and productivity can be improved. The reflective layer 8 may be formed only directly above the current injection region 4a. Moreover, the reflective layer 8 is arranged on an upper side with respect to the current injection region 4a and is formed on the flat electrode layer 6, and thus can be less likely to be influenced by unevenness. This allows its reflectance to be uniform to some extent in a relatively wide region. Thus, the shape of oscillating laser light is further stabilized to allow easier control.

The reflective layer 8 has a diameter (or one side) larger than the diameter (or one side) of the current injection region 4a in a top view. The diameter (one side) of the reflective layer 8 can be in a range of, for example, 1.1 times to 1.5 times the diameter (one side) of the current injection region 4a. Moreover, the reflective layer 8 can include a dielectric multilayer film. The reflective layer 8 can have a configuration similar to the configuration of a semiconductor multilayer film or the dielectric multilayer film exemplified in the multilayer reflective film 11 described above, for example. When the reflective layer 8 is constituted of a dielectric multilayer film, such as a SiO₂/Nb₂O₅, the thickness of each layer is in a range of 40 nm to 100 nm. The number of layers in the multilayer film is 2 or more and can be in a range of, for example, 5 to 20. The entire thickness of the reflective layer 8 is in a range of, for example, 0.08 μm to 2.5 μm, and can be in a range of 0.6 μm to 1.7 μm. The reflective layer 8 is preferably formed separated from an insulating film 7 described below. In other words, the reflective layer 8 is preferably disposed so as not to overlap the insulating film 7 described below in a top view. Thus, the reflective layer 8 having fewer steps can be formed.

Insulating Film 7, p-pad Electrode 9p, and Electrode Layer 9n It is preferable that a portion of the p-side semiconductor layer 4, a portion of the active layer 3, and a portion of the n-side semiconductor layer 2 are removed in the thickness direction and the insulating film 7 is disposed on a portion of the exposed part of the n-side semiconductor layer 2 and on lateral surfaces of the p-side semiconductor layer 4, the active layer 3, and the n-side semiconductor layer 2. The insulating film 7 may cover the upper surface of the p-side semiconductor layer 4, but is preferably disposed to be spaced apart from at least the current injection region 4a of the p-side semiconductor layer 4 in which the reflective layer 8 described above is provided. The insulating film 7 can be made of, for example, an SiOₓ-based material including SiO₂, an SiN_{y}-based material such as SiN, an SiOₓN_{y} material, and an inorganic material such as Ta₂O₅, ZrO₂, AlN, Al₂O₃, and Ga₂O₃. The thickness of the insulating film 7 can be set as appropriate.

A p-pad electrode 9p is preferably disposed on the electrode layer 6. It is preferable that the p-pad electrode 9p is in contact with the electrode layer 6 and has a shape surrounding an outer periphery of the current injection region 4a. With this configuration, a current can be more uniformly injected from the p-pad electrode 9p into the p-side semiconductor layer 4 via the electrode layer 6. Additionally, the p-pad electrode 9p is preferably disposed overlapping the reflective layer 8 described above in a top view. That is, forming the reflective layer 8 after disposing the p-pad electrode 9p allows the p-pad electrode 9p to be disposed overlapping an outer peripheral portion of the reflective layer 8 in a top view.

It is preferable that the electrode layer 9n is disposed on the exposed n-side semiconductor layer 2. Wit this arrangement, the electrode layer 6 and the electrode layer 9n that are configured to supply a current to the vertical cavity surface emitting laser element 10 can be disposed on the same surface side of the semiconductor layered body 5. The p-pad electrode 9p and the electrode layer 9n may be formed in a single layer structure or a layered structure and made of the same material. When the electrode layer 9n and the p-pad electrode 9p are formed in the same layered structure and made of the same material, the electrode layer 9n and the p-pad electrode 9p can be formed in the same step. The p-pad electrode 9p and the electrode layer 9n can be formed of any conductive material used as an electrode in the art. Examples of the conductive material include Ti/Pt/Au and Ti/Rh/Au.

The vertical cavity surface emitting laser element 10 configured as described above can have an improved surface morphology as described above. Thus, it is possible to inhibit a reduction in effective reflectance of the multilayer reflective film 11 and thus to improve the reflectance. The term “effective reflectance” as used herein means a reflectance that does not include a radiation mode and is coupled only to a resonator mode. Improvement in the reflectance of the multilayer reflective film 11 allows for stabilizing characteristics of the vertical cavity surface emitting laser element 10, and, for example, the variation in the threshold current can be reduced.

### EXAMPLE

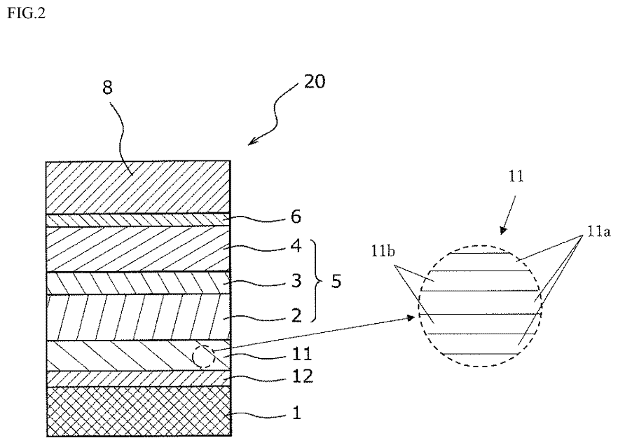

As illustrated in FIG. 2, a GaN substrate having a (0001) plane was used as the substrate 1, and an AlGaN layer (having an Al mixed crystal ratio of 1.6%) was grown to have a thickness of 1 μm as the foundation layer 12 on this substrate 1 by a metal organic chemical vapor deposition method (MOCVD method). On this foundation layer 12, 50 pairs of an Al_{0.8}In_{0.2}N layer 11a (having a thickness of 50 nm) and a GaN layer 11b (having a thickness of 45 nm) were layered by the MOCVD method to form the multilayer reflective film 11. On the multilayer reflective film 11, an n-GaN layer having a thickness of 1.5 μm was layered as the n-side semiconductor layer 2, five pairs of quantum-well layer InGaN (having a thickness of 3 nm)/barrier layer GaN (having a thickness of 2 nm) were layered as the active layer 3, an undoped GaN layer (having a thickness of 25 nm) and an electron-blocking layer AlGaN (having a thickness of 10 nm) were formed as a final barrier layer, and a p-GaN layer (having a thickness of 70 nm) was formed thereon as the p-side semiconductor layer 4, to form the semiconductor layered body 5. On the obtained semiconductor layered body 5, a transparent electrode ITO (having a thickness of 30 nm) was formed as the electrode layer 6 by a sputtering method, a spacer layer Nb₂O₅ (having a thickness of 35 nm) was formed, and a dielectric multilayer film SiO₂ (having a thickness of 75 nm)/Nb₂O₅ (having a thickness of 45 nm) was formed thereon as the reflective layer 8. Thus, a vertical cavity surface emitting laser element structure 20 was formed.

### COMPARATIVE EXAMPLE

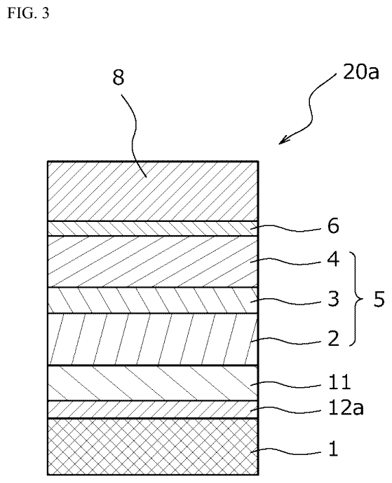

As illustrated in FIG. 3, a structure 20a was formed in a manner similar to the example except that a GaN layer, instead of the AlGaN layer (having an Al mixed crystal ratio of 1.6%), was grown to a thickness of 1 μm as a foundation layer 12a on the substrate 1.

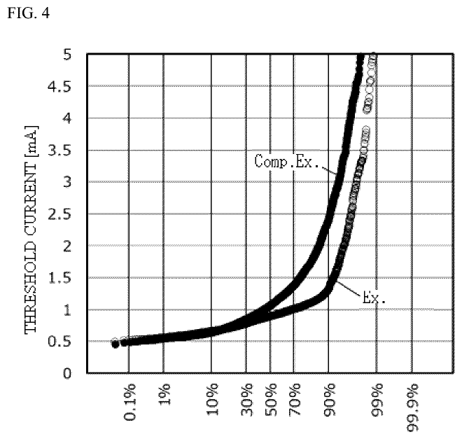

With respect to each of the vertical cavity surface emitting laser element structures 20 obtained in the example and the comparative example, a surface condition immediately after completing the formation of the foundation layer 12 or the foundation layer 12a was observed with a white light interference microscope and the arithmetic average height Sa was evaluated. As a result, it was confirmed that the structure of the example exhibited a good Sa value as compared with the comparative example, and step meandering was inhibited. In addition, a plurality of the vertical cavity surface emitting laser elements 10 configured to emit blue light were manufactured based on the above-described structures, and threshold currents were measured. As a result, as illustrated in FIG. 4, it was confirmed that, compared with the elements according to the comparative example, difference in threshold current between the high percentile region (region of 50 percentile or higher) and the low percentile region is smaller for the elements according to the example than for the elements according to the comparative example, and thus that the variation in the threshold current for each element was able to be reduced. In addition, it was confirmed that the threshold currents in the high percentile regions were lower compared with the case in the comparative example. The horizontal axis of FIG. 4 represents the percentile. The percentile refers to an amount representing a percentage of a position of a certain numerical value with respect to the entire data viewed in ascending order when a plurality of data are arranged in ascending order.

### TEST EXAMPLE

A GaN substrate having a (0001) plane was used as the substrate 1, and an AlGaN layer having a thickness of 1 μm was grown as the foundation layer 12 on this substrate 1 by a metal organic chemical vapor deposition method (MOCVD method). At this time, samples having different Al mixed crystal ratios were formed with variation in the Al mixed crystal ratio of the AlGaN layer in a range of 0% to 8.0%. For each of the obtained samples, a surface condition and occurrence of cracks were examined. As a result, it was confirmed that when the Al mixed crystal ratio of the foundation layer 12 was more than 0.4% to less than 8.0%, good results were obtained regarding the flatness of the surface of the foundation layer 12 and the cracks in each of the obtained samples. Among these, when the Al mixed crystal ratio of the foundation layer 12 was 1.5%, the surface condition of the foundation layer 12 was the best.

What is claimed is:

1. A vertical cavity surface emitting laser element comprising:
a substrate containing GaN;
an AlGaN foundation layer arranged on an upper surface of the substrate;
a multilayer reflective film arranged on an upper surface of the foundation layer and including an AlInN layer; and
an n-side semiconductor layer, an active layer, and a p-side semiconductor layer that are arranged above the multilayer reflective film.

2. The vertical cavity surface emitting laser element according to claim 1, wherein
the foundation layer contains AlₓGa₁₋ₓN, where x is 0.01 or greater and less than 0.08.

3. The vertical cavity surface emitting laser element according to claim 1, wherein
the foundation layer has a thickness of 3.5 μm or less.

4. The vertical cavity surface emitting laser element according to claim 1, wherein
the AlInN layer has an In composition ratio in a range of 1% to 30%.

5. The vertical cavity surface emitting laser element according to claim 1, wherein
the foundation layer is a single crystal layer of AlₓGa₁₋ₓN, where x is 0.01 or greater and less than 0.08.

6. The vertical cavity surface emitting laser element according to claim 1, wherein
the substrate has an off-angle in a range of 0.4° to 10°.

7. The vertical cavity surface emitting laser element according to claim 1, further comprising
an electrode layer and a reflective layer that are arranged over the p-side semiconductor layer.
